(19) United States
(12) Patent Application Publication
(10) Pub. No.: US 2019/0394836 A1
(43) Pub. Date: Dec. 26, 2019

(54) HEATING APPARATUS FOR THE MANUFACTURE OF A SEMICONDUCTOR AND A METHOD OF DRIVING THE SAME

(71) Applicant: SAMSUNG ELECTRONICS CO., LTD., Suwon-si (KR)

(72) Inventors: Young Ho Hwang, Hwaseong-si (KR); Chung Hun Lee, Hwaseong-si (KR)

(21) Appl. No.: 16/178,932

(22) Filed: Nov. 2, 2018

(30) Foreign Application Priority Data
Jun. 22, 2018 (KR) 10-2018-0072080

(51) Int. Cl. H05B 1/02; H01L 21/67; G05D 23/19

(52) U.S. Cl. CPC H05B 1/0233; H05B 1/0202; H01L 21/67103; H05B 2203/002; G05D 23/1931; H05B 2213/07; G05D 23/1917

(57) ABSTRACT

A heating apparatus for manufacturing a semiconductor, the heating apparatus including: a plurality of heaters disposed on a plate; a plurality of temperature sensors configured to sense a temperature of the plate and output a temperature value; a power supply configured to supply power to the plurality of heaters; a plurality of switches disposed between the power supply and the plurality of heaters; and a control unit configured to turn on all of the plurality of switches to heat the plate to a reference temperature, and configured to turn off at least one of the plurality of switches to maintain the reference temperature.

### CROSS-REFERENCE TO RELATED APPLICATION

This application claims priority under 35 U.S.C. § 119 to Korean Patent Application No. 10-2018-0072080, filed on Jun. 22, 2018, the disclosure of which is incorporated by reference herein in its entirety.

### 1. TECHNICAL FIELD

Exemplary embodiments of the inventive concept relate to a heating apparatus for manufacturing a semiconductor and a method of driving the apparatus.

### 2. DESCRIPTION OF RELATED ART

During a photolithography process for forming a desired pattern on a semiconductor wafer, heat is applied to a wafer at a predetermined temperature using a heating apparatus. A conventional heating apparatus uses a large amount of instantaneous power to apply high-temperature heat to the wafer. In addition, the conventional heating apparatus uses a high-voltage alternating current (AC)-direct current (DC) converter to generate the high-temperature heat.

### SUMMARY

According to exemplary embodiments of the inventive concept, there is provided a heating apparatus for manufacturing a semiconductor, the heating apparatus including: a plurality of heaters disposed on a plate; a plurality of temperature sensors configured to sense a temperature of the plate and output a temperature value; a power supply configured to supply power to the plurality of heaters; a plurality of switches disposed between the power supply and the plurality of heaters; and a control unit configured to turn on all of the plurality of switches to heat the plate to a reference temperature, and configured to turn off at least one of the plurality of switches to maintain the reference temperature.

According to exemplary embodiments of the inventive concept, there is provided a heating apparatus for manufacturing a semiconductor, the heating apparatus including: a plate on which a wafer is disposed; a plurality of heaters configured to heat the plate; a plurality of switches connected to the plurality of heaters; and a control unit configured to adjust on/off times of each of the plurality of switches and adjust an average power supplied to each of the plurality of heaters, wherein the plurality of heaters comprise a first heater disposed in a circular shape on a central portion of the plate and a plurality of second heaters disposed around the first heater.

According to exemplary embodiments of the inventive concept, there is provided a method of driving a heating apparatus configured to heat a plate on which a wafer is disposed, the method including: turning on all of a plurality of switches disposed between a plurality of heaters disposed on the plate and a power supply to supply power to the plurality of heaters; heating the plate to a preset reference temperature; and controlling on/off operations of each of the plurality of switches to maintain the preset reference temperature.

### BRIEF DESCRIPTION OF THE DRAWINGS

FIG. 1 is a diagram illustrating a heating apparatus for manufacturing a semiconductor, according to an exemplary embodiment of the inventive concept.

FIG. 2 is a diagram illustrating an arrangement of a plurality of hot wires included in a heater unit shown in FIG. 1, according to an exemplary embodiment of the inventive concept.

FIG. 3 is a diagram of a heating apparatus for manufacturing a semiconductor, according to an exemplary embodiment of the inventive concept.

FIGS. 4A, 4B and 4C are diagrams illustrating switches being turned on or off to adjust a temperature of a heater, according to exemplary embodiments of the inventive concept.

FIG. 5 is an equivalent circuit diagram corresponding to driving operations of the switches shown in FIG. 4A, according to an exemplary embodiment of the inventive concept.

FIG. 6 illustrates the flow of current due to on/off operations of switches, according to an exemplary embodiment of the inventive concept.

FIG. 7 is a diagram illustrating average powers of respective heaters due to on/off operations of the switches shown in FIGS. 4A to 4C, according to an exemplary embodiment of the inventive concept.

FIG. 8 is a diagram illustrating a plurality of heaters arranged in a 3×3 matrix being driven by turning a plurality of switches on or off, according to an exemplary embodiment of the inventive concept.

FIG. 9 is a diagram illustrating time points at which a plurality of switches are turned on or off, according to an exemplary embodiment of the inventive concept.

FIGS. 10A, 10B and 10C are diagrams illustrating switches being turned on or off to adjust a temperature of a heater, according to an exemplary embodiment of the inventive concept.

FIG. 11 is an equivalent circuit diagram corresponding to driving operations of the switches shown in FIG. 10A, according to an exemplary embodiment of the inventive concept.

FIG. 12 is a diagram illustrating average power of each heater relative to on/off operations of switches, according to an exemplary embodiment of the inventive concept.

### DETAILED DESCRIPTION OF THE EMBODIMENTS

A heating apparatus for manufacturing a semiconductor and a method of driving the heating apparatus, according to exemplary embodiments of the inventive concept, will now be described with reference to the accompanying drawings.

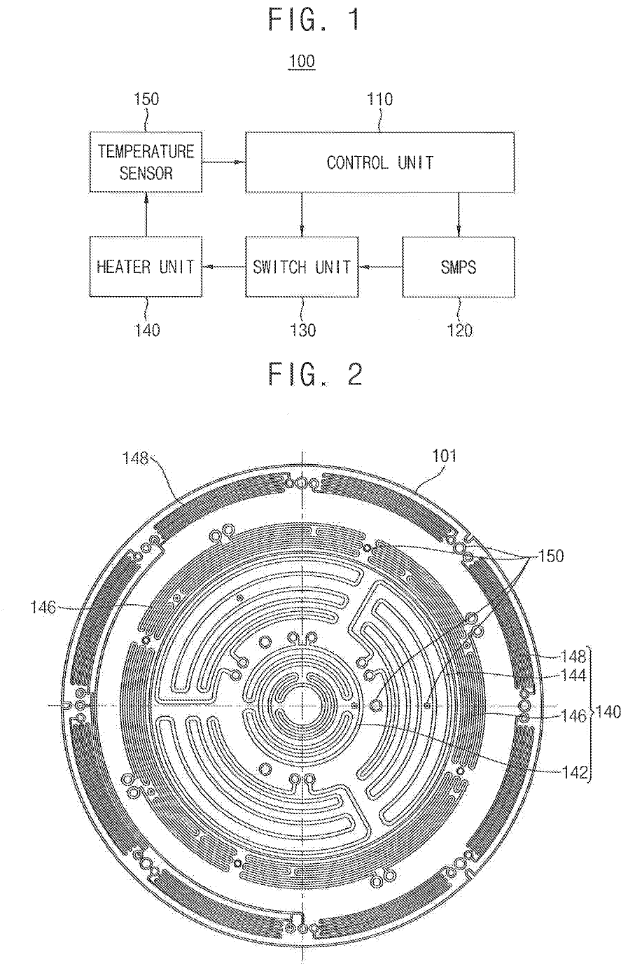

FIG. 1 is a diagram illustrating a heating apparatus 100 for manufacturing a semiconductor, according to an exemplary embodiment of the inventive concept. FIG. 2 is a diagram illustrating an arrangement of a plurality of hot wires included in a heater unit shown in FIG. 1, according to an exemplary embodiment of the inventive concept.

Referring to FIGS. 1 and 2, the heating apparatus 100 for manufacturing a semiconductor, according to an exemplary embodiment of the inventive concept, may include a control unit 110, a switching-mode power supply (SMPS) 120, a switch unit 130, a heater unit 140, and a plurality of temperature sensors 150.

The control unit 110 may control driving operations of the SMPS 120 and the switch unit 130 such that a plate 101 on which a semiconductor wafer is disposed is heated to a set temperature. After the plate 101 is heated to the set temperature, the control unit 110 may control the driving operations of the SMPS 120 and the switch unit 130 according to a current temperature of the plate 101, which is sensed by the temperature sensor 150.

The SMPS 120 may be driven in response to a control signal input by the control unit 110 and generate direct-current (DC) or alternating-current (AC) power. The AC or DC power generated by the SMPS 120 may be supplied to the heater unit 140 via the switch unit 130. The plate 101 may be heated up to the set temperature by power supplied to the heater unit 140. The control unit 110 may control the switch unit 130 to block the supply of power to a hot wire disposed in an area where a current temperature is higher than the set temperature. The control unit 110 may control the switch unit 130 to allow the supply of power to a hot wire disposed in an area where a current temperature is lower than the set temperature.

The SMPS 120 may supply AC power to the heater unit 140. In addition, the SMPS 120 may convert AC power into DC power, and output the DC power to the heater unit 140. The switch unit 130 may be disposed between the SMPS 120 and the heater unit 140.

The heater unit 140 may include a plurality of heaters 142, 144, 146 and 148. The plurality of heaters 142, 144, 146 and 148 may be uniformly disposed in a predetermined pattern on the plate 101 on which a wafer is mounted. The plate 101 may also be referred to hereinafter as a “stage.” Hot wires configured to generate heat due to input power may be referred to as the plurality of heaters 142, 144, 146 and 148.

To apply uniform heat to the wafer, a first heater 142 may be disposed in a circular shape in a central portion of the stage 101, while a plurality of second heaters 144 (e.g., three heaters) may be disposed around the first heater 142. The second heaters 144 may be disposed in a circular arc shape to surround the first heater 142. A plurality of third heaters 146 (e.g., four heaters) may be disposed around the second heaters 144. The third heaters 146 may be disposed in a circular arc shape to surround the second heaters 144. A plurality of fourth heaters 148 (e.g., eight heaters) may be disposed around the third heaters 146. The fourth heaters 148 may be disposed in a circular arc shape to surround the third heaters 146. The respective heaters 142, 144, 146 and 148 may have the same resistance per unit area. The respective heaters 142, 144, 146 and 148 may have the same calorific value. The stage 101 may be uniformly heated by the plurality of heaters 142, 144, 146 and 148.

The switch unit 130 may include a plurality of switches, each of which may be turned on or off in response to a control signal input by the control unit 110. By turning each of the plurality of switches on or off, power may be supplied to the plurality of heaters 142, 144, 146 and 148 included in the heater unit 140.

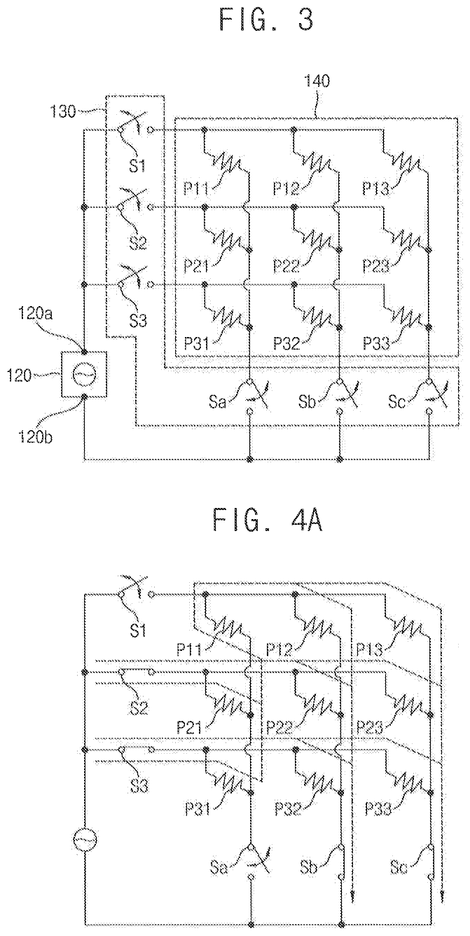

FIG. 3 is a diagram of a heating apparatus for manufacturing a semiconductor, according to an exemplary embodiment of the inventive concept. FIG. 3 illustrates an example in which heaters are disposed in a 3×3 matrix shape and driven by turning a plurality of switches on or off.

As shown in FIG. 3, a plurality of heaters may be disposed in an m×n matrix. A plurality of switches may be used to apply AC power to the matrix of heaters. For example, FIG. 3 illustrates an example in which nine heaters P11, P12, P13, P21, P22, P23, P31, P32 and P33 are disposed in a 3×3 matrix, and first, second and third switches S1, S2, and S3 and fourth, fifth and sixth switches Sa, Sb, and Sc are provided to apply AC power to the nine heaters P11, P12, P13, P21, P22, P23, P31, P32 and P33. A method of supplying AC power to the matrix of heaters and controlling a temperature of the heaters via a multi-channel will be described as an example.

By turning the first to sixth switches S1, S2, S3, Sa, Sb, and Sc on or off, AC power may be selectively supplied to the heaters P11, P12, P13, P21, P22, P23, P31, P32 and P33. The first to third switches S1, S2, and S3 may be connected to a first terminal 120a of an SMPS 120. The fourth to sixth switches Sa, Sb, and Sc may be connected to a second terminal 120b of the SMPS 120. The SMPS 120 may supply AC power to the heater unit 140. The plurality of switches S1 to S3 and Sa to Sc may be turned on or off by the control unit 110. By turning the plurality of switches S1 to S3 and Sa to Sc on or off, AC power may be supplied to each of the heaters P11 to P33 to heat the plate 101 (see the FIG. 2).

A first terminal of the first switch S1 may be connected to the first terminal 120a of the SMPS 120. A second terminal of the first switch S1 may have a common connection to first, second and third heaters P11, P12, and P13. A first terminal of the second switch S2 may be connected to the first terminal 120a of the SMPS 120. A second terminal of the second switch S2 may have a common connection to fourth, fifth and sixth heaters P21, P22, and P23. A first terminal of the third switch S3 may be connected to the first terminal 120a of the SMPS 120. A second terminal of the third switch S3 may have a common connection to seventh, eighth and ninth heaters P31, P32, and P33.

A first terminal of the fourth switch Sa may be connected to the second terminal 120b of the SMPS 120. A second terminal of the fourth switch Sa may have a common connection to the first heater P11, the fourth heater P21, and the seventh heater P31. A first terminal of the fifth switch Sb may be connected to the second terminal 120b of the SMPS 120. A second terminal of the fifth switch Sb may have a common connection to the second heater P12, the fifth heater P22, and the eighth heater P32. A first terminal of the sixth switch Sc may be connected to the second terminal 120b of the SMPS 120. A second terminal of the sixth switch Sc may have a common connection to the third heater P13, the sixth heater P23, and the ninth heater P33.

As shown in FIG. 2, the plurality of heaters 142, 144, 146 and 148 may have the same resistance and be arranged in concentric circular shapes. The respective heaters 142, 144, 146 and 148 may have the same calorific value and the same area. A plurality of temperature sensors 150 may be uniformly disposed at regular intervals in spaces among the plurality of heaters 142, 144, 146 and 148. Each of the plurality of temperature sensors 150 may include a temperature detection element, such as a thermistor. Each of the plurality of temperature sensors 150 may measure a temperature of the plate 101 in real time and transmit a value of the measured temperature to the control unit 110. The respective temperature sensors 150 may be distributed and disposed on the plate 101. A temperature of a portion of the plate 101 on which each of the plurality of temperature sensors 150 is disposed may be measured, and a value of the measured temperature may be transmitted to the control unit 110.

The control unit 110 may adjust a time duration for which each of the plurality of switches S1 to S3 and Sa to Sc is turned off during a control period for which power supplied to the entirety of the heaters 142, 144, 146 and 148 is sequentially controlled. Here, the control period may be a period for controlling on/off operations of all of the plurality of switches S1 to S3 and Sa to Sc once and include a plurality of sub periods according to the number of matrix heaters. In an example, when there are nine matrix heaters, the control period may include nine sub periods. The control unit 110 may supply a switch control signal to the plurality of switches S1 to S3 and Sa to Sc and turn each of the plurality of switches S1 to S3 and Sa to Sc on or off. Initially, all of the plurality of switches S1 to S3 and Sa to Sc may be turned on, and the plate 101 may be heated to a reference temperature. Thereafter, to maintain the plate 101 at the reference temperature, a temperature of the plate 101 may be adjusted by selectively turning off each of the plurality of switches S1 to S3 and Sa to Sc. On/off times of the plurality of switches S1 to S3 and Sa to Sc may be adjusted using a method of reducing power applied to the plurality of heaters P11 to P33. Since average power required by a heater is adjusted by a time duration for which each switch is turned on, a large amount of instantaneous power may not be needed.

Results of a matrix calculation algorithm performed by the control unit 110 may be expressed by Equations 1 and 2. The control unit 110 may calculate time-division switching times (e.g., on/off times) of the plurality of switches S1 to S3 and Sa and Sc based on the results of the matrix calculation algorithm. Power applied to the plurality of heaters P11 to P33 may be adjusted due to the time-division switching of the plurality of switches S1 to S3 and Sa to Sc.

$$\begin{matrix}[ \begin{matrix}{P}_{( L 1 )} - {P}_{on} \\ {P}_{( L 2 )} - {P}_{on} \\ {P}_{( L 3 )} - {P}_{on} \\ {P}_{( 2 , 1 )} - {P}_{on} \\ {P}_{( 2 , 2 )} - {P}_{on} \\ {P}_{( 2 , 3 )} - {P}_{on} \\ {P}_{( 3 , 1 )} - {P}_{on} \\ {P}_{( 3 , 2 )} - {P}_{on} \\ {P}_{( 3 , 3 )} - {P}_{on}\end{matrix} ] = \frac{{P}_{on}}{{n}^{2}} [ \begin{matrix}{K}_{0} - 1 & {K}_{1} - 1 & {K}_{1} - 1 & {K}_{1} - 1 & {K}_{2} - 1 & {K}_{2} - 1 & {K}_{1} - 1 & {K}_{2} - 1 & {K}_{2} - 1 \\ {K}_{1} - 1 & {K}_{0} - 1 & {K}_{1} - 1 & {K}_{2} - 1 & {K}_{1} - 1 & {K}_{2} - 1 & {K}_{2} - 1 & {K}_{1} - 1 & {K}_{2} - 1 \\ {K}_{1} - 1 & {K}_{1} - 1 & {K}_{0} - 1 & {K}_{2} - 1 & {K}_{2} - 1 & {K}_{1} - 1 & {K}_{2} - 1 & {K}_{2} - 1 & {K}_{1} - 1 \\ {K}_{1} - 1 & {K}_{2} - 1 & {K}_{2} - 1 & {K}_{0} - 1 & {K}_{1} - 1 & {K}_{1} - 1 & {K}_{1} - 1 & {K}_{2} - 1 & {K}_{2} - 1 \\ {K}_{2} - 1 & {K}_{1} - 1 & {K}_{2} - 1 & {K}_{1} - 1 & {K}_{0} - 1 & {K}_{1} - 1 & {K}_{2} - 1 & {K}_{1} - 1 & {K}_{2} - 1 \\ {K}_{2} - 1 & {K}_{2} - 1 & {K}_{1} - 1 & {K}_{1} - 1 & {K}_{1} - 1 & {K}_{0} - 1 & {K}_{2} - 1 & {K}_{2} - 1 & {K}_{1} - 1 \\ {K}_{1} - 1 & {K}_{2} - 1 & {K}_{2} - 1 & {K}_{1} - 1 & {K}_{2} - 1 & {K}_{2} - 1 & {K}_{0} - 1 & {K}_{1} - 1 & {K}_{1} - 1 \\ {K}_{2} - 1 & {K}_{1} - 1 & {K}_{2} - 1 & {K}_{2} - 1 & {K}_{1} - 1 & {K}_{2} - 1 & {K}_{1} - 1 & {K}_{0} - 1 & {K}_{1} - 1 \\ {K}_{2} - 1 & {K}_{2} - 1 & {K}_{1} - 1 & {K}_{2} - 1 & {K}_{2} - 1 & {K}_{1} - 1 & {K}_{1} - 1 & {K}_{1} - 1 & {K}_{0} - 1\end{matrix} ] [ \begin{matrix}\overline{{D}_{( 1 , 1 )}} \\ \overline{{D}_{( 1 , 2 )}} \\ \overline{{D}_{( 1 , 3 )}} \\ \overline{{D}_{( 2 , 1 )}} \\ \overline{{D}_{( 2 , 2 )}} \\ \overline{{D}_{( 2 , 3 )}} \\ \overline{{D}_{( 3 , 1 )}} \\ \overline{{D}_{( 3 , 2 )}} \\ \overline{{D}_{( 3 , 3 )}}\end{matrix} ] , & Equation ( 1 ) \\ {P}_{select} = \frac{{( n - 1 )}^{2}}{{( n + 1 )}^{2}} \frac{{V}_{in}^{2}}{R} = {K}_{0} {P}_{on} \\ {P}_{row} = {P}_{col} = \frac{1}{{( n + 1 )}^{2}} {P}_{on} = {K}_{1} {P}_{on} \\ {P}_{ect} = {P}_{on} = {K}_{2} {P}_{on} , & Equation ( 2 )\end{matrix}$$

wherein P_{(1,1)} in Equations (1) and (2) denotes power supplied to the first heater P11 to heat a portion of the plate 101 on which the first heater P11 is disposed, to the reference temperature and maintain the reference temperature. D_{(1,1)} denotes a duty for applying power to the first heater P11, in other words, a time duration for which a switch is turned on to apply power to the first heater P11. P_{(1,2)} denotes power supplied to the second heater P12 to heat a portion of the plate 101 on which the second heater P12 is disposed, to the reference temperature and maintain the reference temperature. D_{(1,2)} denotes a duty for applying power to the second heater P12, in other words, a time duration for which a switch is turned on to apply power to the second heater P12. P_{(1,3)} denotes power supplied to the third heater P13 to heat a portion of the plate 101 on which the third heater P13 is disposed, to the reference temperature and maintain the reference temperature. D_{(1,3)} denotes a duty for applying power to the third heater P13, in other words, a time duration for which a switch is turned on to apply power to the third heater P13.

P_{(2,1)} denotes power supplied to the fourth heater P21 to heat a portion of the plate 101 on which the fourth heater P21 is disposed, to the reference temperature and maintain the reference temperature. D_{(2,1)} denotes a duty for applying power to the fourth heater P21, in other words, a time duration for which a switch is turned on to apply power to the fourth heater P21. P_{(2,2)} denotes power supplied to the fifth heater P22 to heat a portion of the plate 101 on which the fifth heater P22 is disposed, to the reference temperature and maintain the reference temperature. D_{(2,2)} denotes a duty for applying power to the fifth heater P22, in other words, a time duration for which a switch is turned on to apply power to the fifth heater P22. P_{(2,3)} denotes power supplied to the sixth heater P23 to heat a portion of the plate 101 on which the sixth heater P23 is disposed, to the reference temperature and maintain the reference temperature. D_{(2,3)} denotes a duty for applying power to the sixth heater P23, in other words, a time duration for which a switch is turned on to apply power to the sixth heater P23.

P_{(3,1)} denotes power supplied to the seventh heater P31 to heat a portion of the plate 101 on which the seventh heater P31 is disposed, to the reference temperature and maintain the reference temperature. D_{(3,1)} denotes a duty for applying power to the seventh heater P31, in other words, a time duration for which a switch is turned on to apply power to the seventh heater P31. P_{(3,2)} denotes power supplied to the eighth heater P32 to heat a portion of the plate 101 on which the eighth heater P32 is disposed, to the reference temperature and maintain the reference temperature. D_{(3,2)} denotes a duty for applying power to the eighth heater P32, in other words, a time duration for which a switch is turned on to apply power to the eighth heater P32. P_{(3,3)} denotes power supplied to the ninth heater P33 to heat a portion of the plate 101 on which the ninth heater P33 is disposed, to the reference temperature and maintain the reference temperature. D_{(3,3)} denotes a duty for applying power to the ninth heater P33, in other words, a time duration for which a switch is turned on to apply power to the ninth heater P33.

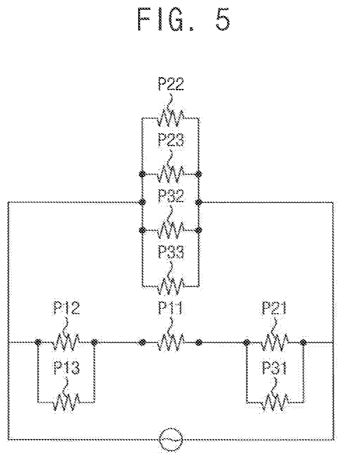

Still referring to Equations 1 and 2, P_{select} denotes power applied to a heater P11 of FIG. 5, which is an example of a temperature-adjusting heater. P_{row} denotes power applied to heaters P12, P13, P21, and P31 of FIG. 5, which are examples of at least one heater connected to the heater P11 of FIG. 5, in a lateral direction and/or a longitudinal direction. In other words, P_{row} denotes power applied to the heaters P12, P13, P21, and P31 of FIG. 5, which are examples of at least one heater that is directly connected to and disposed adjacent to the heater P11 of FIG. 5.

P_{ect} denotes power applied to heaters P22, P23, P32, and P33 of FIG. 5. K₀ denotes a relationship between maximum power Pₒₙ and the power P_{select} applied to the heater P11 of FIG. 5. K₁ denotes a relationship between the maximum power Pₒₙ and the power P_{row} applied to the heaters P12, P13, P21, and P31 of FIG. 5. K₂ denotes a relationship between the maximum power Pₒₙ and the power Pa applied to the heaters P22, P23, P32, and P33 of FIG. 5. n denotes the number of matrix heaters (e.g., n=3 in the case of a 3×3 matrix). Pₒₙ denotes, e.g., the maximum power that may be applied to a heater at an applied voltage Vᵢₙ.

Result values of the 3×3 matrix heaters based on Equations 1 and 2 may be expressed as shown in Table 1.

TABLE 1

| | | | | | | | | |
|---|---|---|---|---|---|---|---|---|
| −0.75 | −0.9375 | −0.9375 | −0.9375 | 0 | 0 | −0.9375 | 0 | 0 |
| −0.9375 | −0.75 | −0.9375 | 0 | −0.9375 | 0 | 0 | −0.9375 | 0 |
| −0.9375 | −0.9375 | −0.75 | 0 | 0 | −0.9375 | 0 | 0 | −0.9375 |
| −0.9375 | 0 | 0 | −0.75 | −0.9375 | −0.9375 | −0.9375 | 0 | 0 |
| 0 | −0.9375 | 0 | −0.9375 | −0.75 | −0.9375 | 0 | −0.9375 | 0 |
| 0 | 0 | −0.9375 | −0.9375 | −0.9375 | −0.75 | 0 | 0 | −0.9375 |
| −0.9375 | 0 | 0 | −0.9375 | 0 | 0 | −0.75 | −0.9375 | −0.9375 |
| 0 | −0.9375 | 0 | 0 | −0.9375 | 0 | −0.9375 | −0.75 | −0.9375 |
| 0 | 0 | −0.9375 | 0 | 0 | −0.9375 | −0.9375 | −0.9375 | −0.75 |

The control unit 110 may turn on all of the plurality of switches S1, S2, S3, Sa, Sb, and Sc to heat the plate 101 to a set reference temperature, and control an off time of each of the plurality of switches S1, S2, S3, Sa, Sb, and Sc to maintain a reference temperature. The control unit 110 may calculate average power supplied to each of the plurality of heaters P11 to P33 to maintain the plate 101 at the reference temperature. The control unit 110 may calculate on/off times of each of the plurality of switches S1, S2, S3, Sa, Sb, and Sc to maintain the plate 101 at the reference temperature. The control unit 110 may control on/off operations of each of the plurality of switches S1, S2, S3, Sa, Sb, and Sc based on the calculated on/off times of each of the plurality of switches S1, S2, S3, Sa, Sb, and Sc.

By supplying AC power to the plurality of heaters P11 to P33, the control unit 110 may calculate a phase angle of the AC power using a result of a matrix calculation algorithm of Equations land 2. The control unit 110 may calculate a time-division switching time based on the phase angle of the AC power based on Equation 3. The control unit 110 may control an on time Pₒₙ of each of the plurality of switches S1, S2, S3, Sa, Sb, and Sc based on the time-division switching time.

$${P}_{on} = \frac{{( {V}_{RMS} )}^{2}}{R} = \frac{{V}_{do}^{2}}{R} D \\ {P}_{on} = \frac{{( {V}_{RMS} )}^{2}}{R} = \frac{{V}_{P}^{2}}{R} \{ \frac{1}{π} ( π - α + \frac{sin 2 α}{2} ) \} , \qquad Equation ( 3 )$$

wherein D in Equation (3) denotes the time-division switching time, and

$$\{ \frac{1}{π} ( π - α + \frac{sin 2 α}{2} ) \}$$

denotes the phase angle.

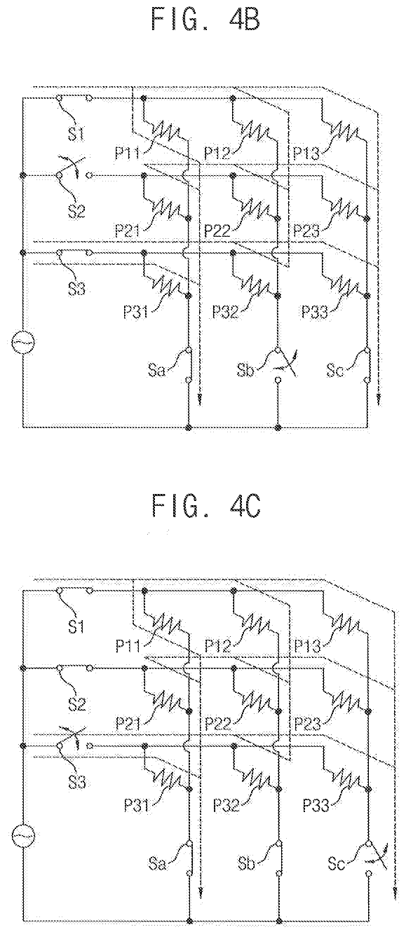

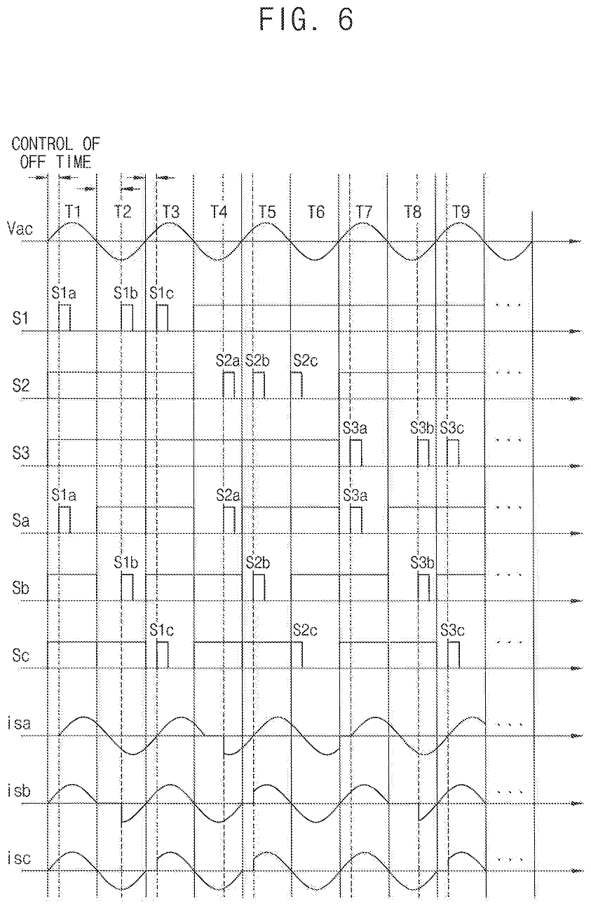

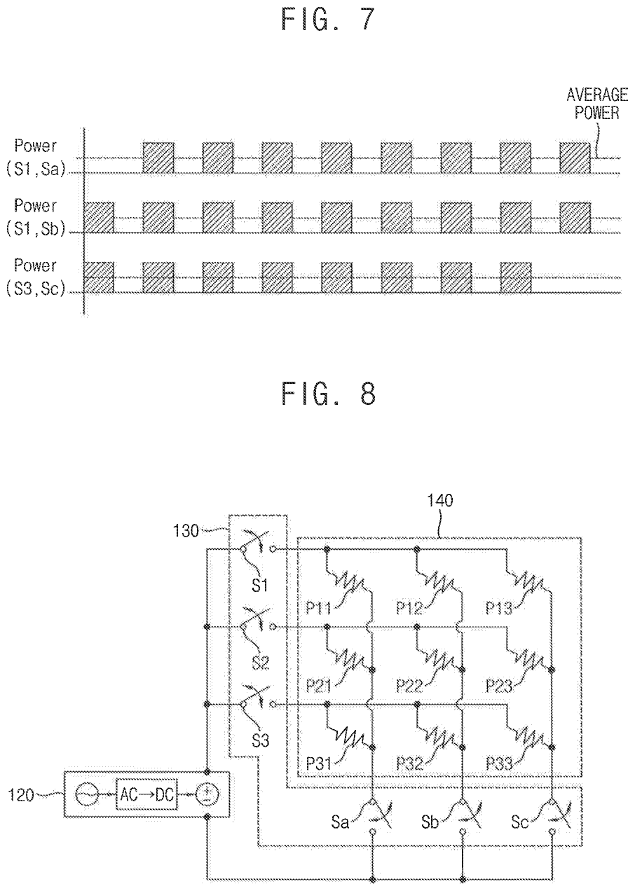

FIGS. 4A to 4C are diagrams illustrating switches being turned on or off to adjust a temperature of a heater, according to an exemplary embodiment of the inventive concept. FIG. 5 is an equivalent circuit diagram corresponding to driving operations of the switches shown in FIG. 4A, according to an exemplary embodiment of the inventive concept. FIG. 6 illustrates the flow of current due to on/off operations of switches, according to an exemplary embodiment of the inventive concept. FIG. 7 is a diagram illustrating average powers of respective heaters due to on/off operations of the switches shown in FIGS. 4A to 4C, according to an exemplary embodiment of the inventive concept.

Referring to FIGS. 4A to 4C and 5 to 7, the control unit 110 may supply a switch control signal to a plurality of switches S1 to S3 and Sa to Sc and turn each of the plurality of switches S1 to S3 and Sa to Sc on or off. The plurality of switches S1 to S3 and Sa to Sc may all be initially turned on and subsequently turned off in a selective manner to control a temperature. Since AC power is supplied from the SMPS 120 to the heater unit 140, the control unit 110 may turn the plurality of switches S1 to S3 and Sa to Sc on or off based on a time-division switching time and a phase angle of the AC power.

The control unit 110 may calculate the phase angle of the AC power using results of a matrix calculation algorithm of Equations 1 and 2. The control unit 110 may calculate the time-division switching time based on Equation 3 according to the calculated phase angle of the AC power and control on/off operations of each of the plurality of switches S1 to S3 and Sa to Sc. Power applied to the plurality of heaters P11 to P33 may be reduced by adjusting an off time of each of the plurality of switches S1 to S3 and Sa to Sc. Since the average power required by a heater (e.g., one of P11 to P33) is adjusted by a time duration for which each switch (e.g., S1 to S3 and Sa to Sc) is turned on, a large amount of instantaneous power is not needed. For example, the average power when the S1 switch and the Sa switch are turned on is shown in FIG. 7. For example, the average power when the S1 switch and the Sb switch are turned on is shown in FIG. 7. For example, the average power when the S3 switch and the Sc switch are turned on is shown in FIG. 7.

In an example, as shown in FIGS. 4A and 6, a second switch S2, a third switch S3, a fifth switch Sb, and a sixth switch Sc may be turned on from a start time point of a first sub period T1 to an end time point thereof. In reference to FIG. 6, a switch is on if its signal is high. A first switch S1 and a fourth switch Sa may be turned off for a predetermined duration of time from the start time point of the first sub period T1, and then, be turned on for a predetermined duration of time. In reference to FIG. 6, a switch is off if its signal is low. In this case, the first switch S1 and the fourth switch Sa may be changed from an off state into an on state (see S1a go high) in a first half of the first sub period T1. Subsequently, e.g., in a second half of the first sub period T1, the first switch S1 and the fourth switch Sa may be turned off (see S1a go low), and remain in an off state to the end time point of the first sub period T1. Current flow through the fourth switch Sa in the first sub period T1 is shown by isa, current flow through the fifth switch Sb in the first sub period T1 is shown by isb, and current flow through the sixth switch Sc in the first sub period T1 is shown by isc, for example. It is to be understood that isa, isb and isc represent current flows of the aforementioned switches in the remaining sub periods to be discussed hereinafter.

As shown in FIG. 6, the second switch S2, the third switch S3, the fourth switch Sa, and the sixth switch Sc may be turned on from a start time point of a second sub period T2 to an end time point thereof. The first switch S1 and the fifth switch Sb may be turned off for a predetermined duration of time from the start time point of the second sub period T2, and then, be turned on for a predetermined duration of time. In this case, the first switch S1 and the fourth switch Sa may be changed from an off state into an on state (see S1b go high) in a latter half of the second sub period T2. Subsequently, the first switch S1 and the fifth switch Sb may be turned off (see S1b go low), and remain in an off state to the end time point of the second sub period T2.

As shown in FIG. 6, the second switch S2, the third switch S3, the fourth switch Sa, and the fifth switch Sb may be turned on from a start time point of a third sub period T3 to an end time point thereof. The first switch S1 and the sixth switch Sc may be turned off for a predetermined duration of time from the start time point of the third sub period T3, and then, be placed in an on state for a predetermined duration of time (see S1c). In this case, the first switch S1 and the sixth switch Sc may be changed from an off state into an on state (see Sic go high) in a first half of the third sub period T3. Subsequently, the first switch S1 and the sixth switch Sc may be turned off (see S1c go low) and remain in an off state to the end time point of the third sub period T3.

As shown in FIG. 6, the first switch S1, the third switch S3, the fifth switch Sb, and the sixth switch Sc may be turned on from a start time point of a fourth sub period T4 to an end time point thereof. The second switch S2 and the fourth switch Sa may be turned off for a predetermined duration of time from the start time point of the fourth sub period T4, and then, be placed in an on state for a predetermined duration of time (see S2a). In this case, the second switch S2 and the fourth switch Sa may be changed from an off state into an on state (see S2a go high) in a latter half of the fourth sub period T4. Subsequently, the second switch S2 and the fourth switch Sa may be turned off (see S2a go low) and remain in an off state to the end time point of the fourth sub period T4.

As shown in FIGS. 4B and 6, the first switch S1, the third switch S3, the fourth switch Sa, and the sixth switch Sc may be turned on from a start time point of a fifth sub period T5 to an end time point thereof. The second switch S2 and the fifth switch Sb may be turned off for a predetermined duration of time from the start time point of the fifth sub period T5, and then, be placed in an on state for a predetermined duration of time (see S2b). In this case, the second switch S2 and the fifth switch Sb may be changed from an off state into an on state (see S2b go high) in a first half of the fifth sub period T5. Subsequently, the second switch S2 and the fifth switch Sb may be turned off (see S2b go low) and remain in an off state to the end time point of the fifth sub period T5.

As shown in FIG. 6, the first switch S1, the third switch S3, the fourth switch Sa, and the fifth switch Sb may be turned on from a start time point of a sixth sub period T6 to an end time point thereof. The second switch S2 and the sixth switch Sc may be turned on for a predetermined duration of time from the start time point of the sixth sub period T6, and then, remain in an off state to the end time point of the sixth sub period T6 (see S2c). In this case, the second switch S2 and the sixth switch Sc may be changed from an on state into an off state in a first half of the sixth sub period T6.

As shown in FIG. 6, the first switch S1, the second switch S2, the fifth switch Sb, and the sixth switch Sc may be turned on from a start time point of a seventh sub period T7 to an end time point thereof. The third switch S3 and the fourth switch Sa may be turned off for a predetermined duration of time from the start time point of the seventh sub period T7, and then, be placed in an on state for a predetermined duration of time. In this case, the third switch S3 and the fourth switch Sa may be changed from an off state into an on state (see S3a go high) in a first half of the seventh sub period T7. Subsequently, the third switch S3 and the fourth switch Sa may be turned off (see S3a go low) and remain in an off state to the end time point of the seventh sub period T7.

As shown in FIG. 6, the first switch S1, the second switch S2, the fourth switch Sa, and the sixth switch Sc may be turned on from a start time point of an eighth sub period T8 to an end time point thereof. The third switch S3 and the fifth switch Sb may be turned off for a predetermined duration of time from the start time point of the eighth sub period T8, and then, be placed in an on state for a predetermined duration of time. In this case, the third switch S3 and the fifth switch Sb may be changed from an off state into an on state (see S3b go high) in a latter half of the eighth sub period T8. Subsequently, the third switch S3 and the fifth switch Sb may be turned off (see S3b go low) and remain in an off state to the end time point of the eighth sub period T8.

As shown in FIGS. 4C and 6, the first switch S, the second switch S2, the fourth switch Sa, and the fifth switch Sb may be turned on from a start time point of a ninth sub period T9 to an end time point thereof. The third switch S3 and the sixth switch Sc may be turned off for a predetermined duration of time from the start time point of the ninth sub period T9, and then, be placed in an on state for a predetermined duration of time. In this case, the third switch S3 and the sixth switch Sc may be changed from an off state into an on state (see S3c go high) in a first half of the ninth sub period T9. Subsequently, the third switch S3 and the sixth switch Sc may be turned off (see S3c go low) and remain in an off state to the end time point of the ninth sub period T9.

As described above, after the plate 101 is heated to the reference temperature, the control unit 110 may adjust on/off times of each of the plurality of switches S1 to S3 and Sa to Sc based on a temperature value received from the temperature sensor 150 and the reference temperature. The control unit 110 may adjust the on/off times of each of the plurality of switches S1 to S3 and Sa to Sc, so that average power supplied to each of the plurality of heaters P11 to P33 may be adjusted. The control unit 110 may adjust a time duration for which each of the plurality of switches S1 to S3 and Sa to Sc is turned on or off and maintain the average power supplied to each of the plurality of heaters P11 to P33 to be constant (see FIG. 7). The control unit 110 may calculate power to be applied to the heater P11 of FIG. 5, which is an example of a first heater configured to adjust a temperature, from among the plurality of heaters P11 to P33. The control unit 110 may adjust an off time of at least one switch connected to the first heater, from among the plurality of switches S1 to S3 and Sa to Sc, based on the calculation result of the power to be applied to the first heater.

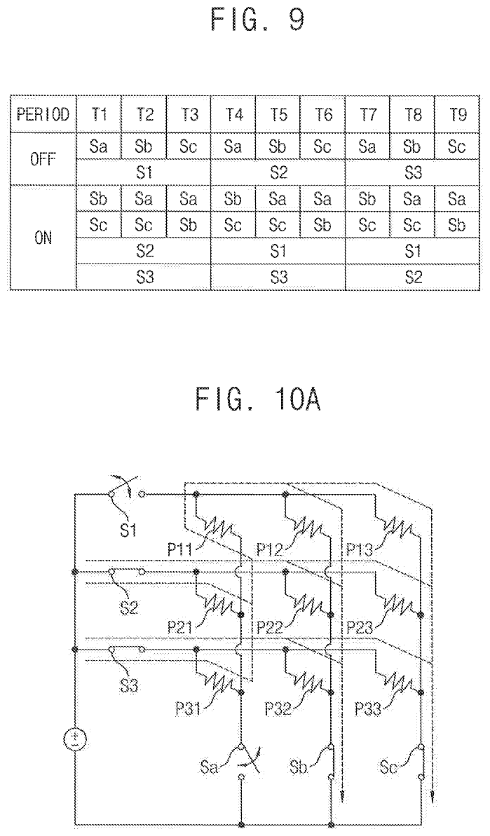

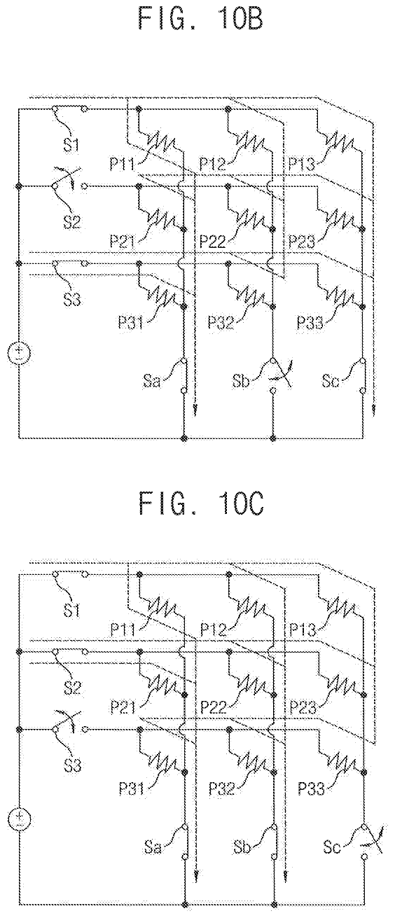

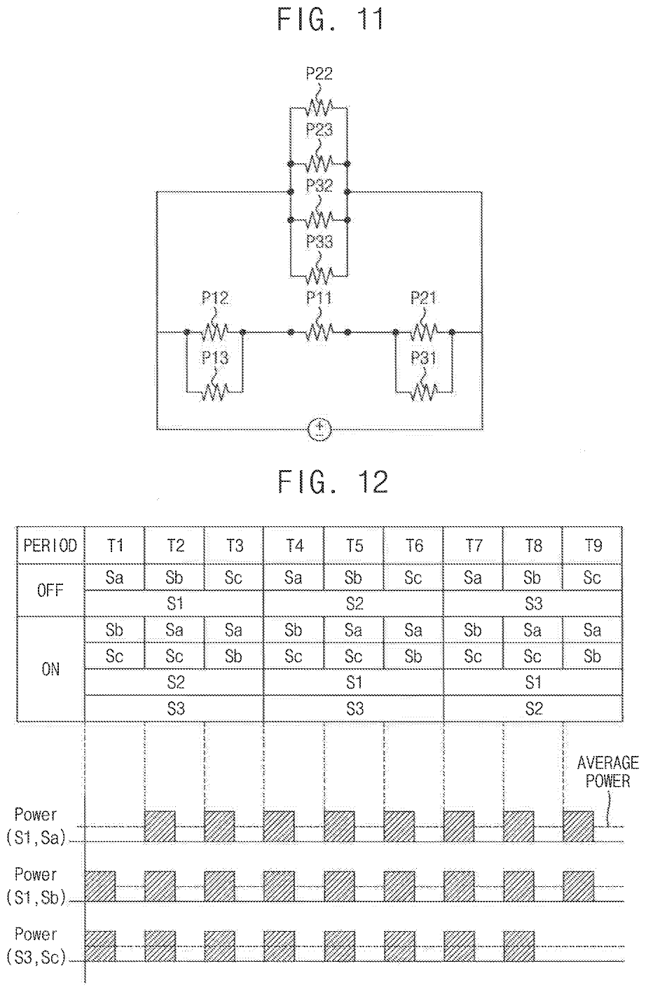

FIG. 8 is a diagram illustrating a plurality of heaters arranged in a 3×3 matrix being driven by turning a plurality of switches on or off, according to an exemplary embodiment of the inventive concept. FIG. 9 is a diagram illustrating time points at which a plurality of switches are turned on or off, according to an exemplary embodiment of the inventive concept. FIGS. 10A to 10C are diagrams illustrating switches being turned on or off to adjust a temperature of a heater, according to an exemplary embodiment of the inventive concept. FIG. 11 is an equivalent circuit diagram corresponding to driving operations of the switches shown in FIG. 10A, according to an exemplary embodiment of the inventive concept.

Referring to FIGS. 1, 2 and 8 to 11, the control unit 110 may turn on the plurality of switches S1 to S3 and Sa to Sc disposed between the plurality of heaters P11 to P33 located on the plate 101 and the SMPS 120 and supply DC power to the plurality of heaters P11 to P33. The plate 101 may be heated to a preset reference temperature by supplying power to the plurality of heaters P11 to P33. After the plate 101 is heated to the reference temperature, the control unit 110 may adjust an on/off time of each of the plurality of switches S1 to S3 and Sa to Sc based on a temperature value received from the temperature sensor 150 and the reference temperature. The control unit 110 may adjust the on/off time of each of the plurality of switches S1 to S3 and Sa to Sc, so that average power supplied to each of the plurality of heaters P11 to P33 may be adjusted.

The control unit 110 may adjust a time duration for which each of the plurality of switches S1 to S3 and Sa to Sc is turned off during a control period for which power supplied to all of the heaters P11 to P33 is sequentially controlled. Here, the control period may be a period for controlling on/off operations of all of the plurality of switches S1 to S3 and Sa to Sc once and include a plurality of sub periods according to the number of matrix heaters. It is to be understood that the matrix heaters may refer to the heaters P11 to P33. In an example, when the matrix heaters are arranged in a 3×3 matrix shape, the control period may include nine sub periods. The control unit 110 may supply a switch control signal to the plurality of switches S S1 to S3 and Sa to Sc and turn each of the plurality of switches S1 to S3 and Sa to Sc on or off. Initially, all of the plurality of switches S1 to S3 and Sa to Sc may be turned on, and the plate 101 may be heated to a reference temperature. Subsequently, each of the plurality of switches S1 to S3 and Sa to Sc may be selectively turned off to maintain the plate 101 at the reference temperature. In other words, a temperature of the plate 101 may be adjusted. On/off times of the plurality of switches S1 to S3 and Sa to Sc may be adjusted using a method of reducing power applied to the plurality of heaters P11 to P33. Since average power required by each of the heaters P11 to P33 is adjusted by a time duration for which each of the switches S1 to S3 and Sa to Sc is turned on, a large amount of instantaneous power is not needed.

In an example, as shown in FIGS. 9 and 10A, in a first sub period T1, a first switch S1 and a fourth switch Sa may be turned off, and a second switch S2, a third switch S3, a fifth switch Sb, and a sixth switch Sc may be turned on so that power may be supplied to the plurality of heaters P11 to P33. FIG. 10A illustrates the flow of current relative to on/off operations of the switches S1 to S3 and Sa to Sc in the first sub period T1.

As shown in FIG. 9, in a second sub period T2, the first switch S1 and the fifth switch Sb may be turned off, and the second switch S2, the third switch S3, the fourth switch Sa, and the sixth switch Sc may be turned on, so that power may be supplied to the plurality of heaters P11 to P33.

As shown in FIG. 9, in a third sub period T3, the first switch S1 and the sixth switch Sc may be turned off, and the second switch S2, the third switch S3, the fourth switch Sa, and the fifth switch Sb may be turned on, so that power may be supplied to the plurality of heaters P11 to P33.

As shown in FIG. 9, in a fourth sub period T4, the second switch S2 and the fourth switch Sa may be turned off, and the first switch S1, the third switch S3, the fifth switch Sb, and the sixth switch Sc may be turned on, so that power may be supplied to the plurality of heaters P11 to P33.

As shown in FIGS. 9 and 10B, in a fifth sub period T5, the second switch S2 and the fifth switch Sb may be turned off, and the first switch S1, the third switch S3, the fourth switch Sa, and the sixth switch Sc may be turned on, so that power may be supplied to the plurality of heaters P1 to P33.

As shown in FIG. 9, in a sixth sub period T6, the second switch S2 and the sixth switch Sc may be turned off, and the first switch S1, the third switch S3, the fourth switch Sa, and the fifth switch Sb may be turned on, so that power may be supplied to the plurality of heaters P11 to P33.

As shown in FIG. 9, in a seventh sub period T7, the third switch S3 and the fourth switch Sa may be turned off, and the first switch S1, the second switch S2, the fifth switch Sb, and the sixth switch Sc may be turned on, so that power may be supplied to the plurality of heaters P11 to P33.

As shown in FIG. 9, in an eighth sub period T8, the third switch S3 and the fifth switch Sb may be turned off, and the first switch S1, the second switch S2, the fourth switch Sa, and the sixth switch Sc may be turned on, so that power may be supplied to the plurality of heaters P11 to P33.

As shown in FIGS. 9 and 10C, in a ninth sub period T9, the third switch S3 and the sixth switch Sc may be turned off, and the first switch S1, the second switch S2, the fourth switch Sa, and the fifth switch Sb may be turned on, so that power may be supplied to the plurality of heaters P11 to P33. As described above, the control unit 110 may control power applied to a heater of which a temperature is desired to be adjusted by selectively turning the first to third switches S1 to S3 and the fourth to sixth switches Sa to Sc on or off.

FIG. 12 is a diagram illustrating average power of each heater relative to on/off operations of switches, according to an exemplary embodiment of the inventive concept.

Referring to FIG. 12, the control unit 110 may calculate power applied to each of the heaters P11 to P33 based on Equations 1 and 2. The control unit 110 may determine time-division switching times of the first to third switches S1 to S3 and fourth to sixth switches Sa to Sc based on Equation 3 according to a power calculation result. In other words, the control unit 110 may determine time points at which the first to third switches S1 to S3 and the fourth to sixth switches Sa to Sc are turned on or off and duties at which the first to third switches S1 to S3 and the fourth to sixth switches Sa to Sc are turned on. The control unit 110 may control the first to third switches S1 to S3 and the fourth to sixth switches Sa to Sc based on the determined on/off time points and duties, and adjust power applied to each of the heaters P11 to P33. For example, the average power when the S1 switch and the Sa switch are turned on is shown in FIG. 12. For example, the average power when the S1 switch and the Sb switch are turned on is shown in FIG. 12. For example, the average power when the S3 switch and the Sc switch are turned on is shown in FIG. 12. Thus, power applied to the plurality of heaters P11 to P33 may be gradually reduced by selectively turning off the plurality of switches S1 to S3 and Sa to Sc. Further, by adjusting time durations for which the plurality of switches S1 to S3 and Sa to Sc are turned on, the average power may be maintained to be constant, and consumption of a large amount of instantaneous power may be prevented.

AC power may be supplied to the matrix heater, and the control unit 110 may initially turn on all of the plurality of switches S1 to S3 and Sa to Sc so that the plate 101 may be heated to a reference temperature. The control unit 110 may adjust on/off operations of the plurality of switches S1 to S3 to Sa to Sc according to a phase angle of the AC power so that power may be selectively supplied to the plurality of heaters P11 to P33. By adjusting off times and on times of the plurality of switches S1 to S3 and Sa to Sc, power applied to a heater of which a temperature is desired to be adjusted may be adjusted. Since application of an AC-DC converter is not required by using AC power, the size and cost of a heating apparatus may be reduced.

Even in a case in which the AC-DC converter is applied, the control unit 110 may initially turn on all of the plurality of switches S1 to S3 and Sa to Sc so that the plate 101 may be heated to the reference temperature. Power may be selectively supplied to the plurality of heaters P11 to P33 by adjusting on/off operations of the plurality of switches S1 to S3 and Sa to Sc. The control unit 110 may control off times of switches connected to a heater of which a temperature is desired to be adjusted, thereby adjusting average power of each heater.

According to exemplary embodiments of the inventive concept, on/off times of a plurality of switches can be adjusted by using a method of reducing power applied to a plurality of heaters. Since average power required by a heater is adjusted by a time duration for which each switch is turned on, a large amount of instantaneous power is not needed.

According to exemplary embodiments of the inventive concept, AC power can be supplied to matrix heaters, and on/off operations of the plurality of switches can be adjusted according to a phase angle of the AC power, thereby adjusting power applied to a heater of which a temperature is desired to be adjusted. Since the application of an AC-DC converter is not required by using AC power, the size and cost of a heating apparatus can be reduced.

While the inventive concept has been particularly shown and described with reference to exemplary embodiments thereof, it should be understood by those skilled in the art that various modifications may be made thereto without departing from the scope of the inventive concept as defined by the following claims.

What is claimed is:

1. A heating apparatus for manufacturing a semiconductor, the heating apparatus comprising:
a plurality of heaters disposed on a plate;
a plurality of temperature sensors configured to sense a temperature of the plate and output a temperature value;
a power supply configured to supply power to the plurality of heaters;
a plurality of switches disposed between the power supply and the plurality of heaters; and
a control unit configured to turn on all of the plurality of switches to heat the plate to a reference temperature, and configured to turn off at least one of the plurality of switches to maintain the reference temperature.

2. The heating apparatus of claim 1, wherein the control unit calculates average power supplied to each of the plurality of heaters and on/off times of each of the plurality of switches, and controls on/off operations of the plurality of switches based on the on/off times of each of the plurality of switches to maintain the plate at the reference temperature.

3. The heating apparatus of claim 2, wherein the control unit calculates the on/off times of each of the plurality of switches based on a number of the plurality of heaters, a resistance of each of the plurality of heaters, and a power supplied to each of the plurality of heaters.

4. The heating apparatus of claim 2, wherein the control unit adjusts time durations for which each of the plurality of switches is turned on or off and keeps the average power supplied to each of the plurality of heaters constant.

5. The heating apparatus of claim 2, wherein the control unit adjusts a time duration for which each of the plurality of switches is turned off, during a control period in which on/off operations of each of the plurality of switches are controlled once.

6. The heating apparatus of claim 1, wherein the control unit calculates power to be applied to a first heater of which a temperature is to be adjusted, from among the plurality of heaters, and adjusts an off time of at least one switch, from among the plurality of switches, based on a calculation result of the power to be applied to the first heater.

7. The heating apparatus of claim 1, wherein the power supply supplies alternating-current (AC) power to the plurality of heaters.

8. The heating apparatus of claim 7, wherein the control unit calculates a time-division switching time of the plurality of switches based on a phase angle of the AC power, and controls on/off times of each of the plurality of switches based on the time-division switching time.

9. The heating apparatus of claim 8, wherein the plurality of heaters comprise a first heater, a second heater connected to and disposed adjacent to the first heater, and a third heater,
wherein the control unit adjusts off times of switches to be connected to the first heater, from among the plurality of switches, to adjust the temperature of the first heater, and turns on switches from among the plurality of switches connected to the second heater and the third heater.

10. A heating apparatus for manufacturing a semiconductor, the heating apparatus comprising:
a plate on which a wafer is disposed;
a plurality of heaters configured to heat the plate;
a plurality of switches connected to the plurality of heaters; and
a control unit configured to adjust on/off times of each of the plurality of switches and adjust an average power supplied to each of the plurality of heaters,
wherein the plurality of heaters comprise a first heater disposed in a circular shape on a central portion of the plate and a plurality of second heaters disposed around the first heater.

11. The heating apparatus of claim 10, wherein the plurality of second heaters are disposed in a circular arc shape to surround the first heater.

12. The heating apparatus of claim 11, wherein the plurality of heaters further comprise a plurality of third heaters disposed in a circular arc shape to surround the plurality of second heaters.

13. The heating apparatus of claim 12, wherein the plurality of heaters further comprise a plurality of fourth heaters disposed in a circular arc shape to surround the plurality of third heaters.

14. The heating apparatus of claim 13, wherein the first heater, the plurality of second heaters, the plurality of third heaters, and the plurality of fourth heaters have the same resistance per unit area.

15. The heating apparatus of claim 13, wherein respective calorific values of the first heater, the plurality of second heaters, the plurality of third heaters, and the plurality of fourth heaters are the same.

16. A method of driving a heating apparatus configured to heat a plate on which a wafer is disposed, the method comprising:
turning on all of a plurality of switches disposed between a plurality of heaters disposed on the plate and a power supply to supply power to the plurality of heaters;
heating the plate to a preset reference temperature; and
controlling on/off operations of each of the plurality of switches to maintain the preset reference temperature.

17. The method of claim 16, wherein the controlling of the on/off operations of each of the plurality of switches comprises calculating an average power supplied to each of the plurality of heaters and on/off times of each of the plurality of switches and the on/off operations of the plurality of switches are controlled based on the on/off times of each of the plurality of switches.

18. The method of claim 17, further comprising calculating power to be applied to a first heater of which a temperature is to be adjusted, from among the plurality of heaters, and adjusting the on/off times of at least one of the plurality of switches based on a result of the calculation of the power to be applied to the first heater.

19. The method of claim 18, wherein the power supply supplies alternating-current (AC) power to the plurality of heaters,
wherein a control unit calculates a time-division switching time of the plurality of switches based on a phase angle of the AC power, and controls the on/off times of each of the plurality of switches based on the time-division switching time.

20. The method of claim 19, wherein the plurality of heaters comprise the first heater, a second heater connected to and disposed adjacent to the first heater, and a third heater,
wherein the control unit adjusts off times of switches to be connected to the first heater, from among the plurality of switches, to adjust the temperature of the first heater, and turns on switches from among the plurality of switches connected to the second heater and the third heater.
